(19) United States
(12) Patent Application Publication
(10) Pub. No.: US 2024/0397627 A1
(43) Pub. Date: Nov. 28, 2024

(54) BOARD UNIT, MEMORY SYSTEM, AND ELECTRONIC DEVICE

(71) Applicant: Kioxia Corporation, Tokyo (JP)

(72) Inventor: Shiro HARASHIMA, Sagamihara (JP)

(73) Assignee: Kioxia Corporation, Tokyo (JP)

(21) Appl. No.: 18/797,605

(22) Filed: Aug. 8, 2024

Related U.S. Application Data
(63) Continuation of application No. PCT/JP2022/005423, filed on Feb. 10, 2022.

(51) Int. Cl. H05K 1/18

(52) U.S. Cl. CPC H05K 1/18; H05K 2201/10159; H05K 2201/10787

(57) ABSTRACT

A board unit of an embodiment includes a board, an electronic component, and a connection portion. The electronic component is on the board. The connection portion connects the board and the electronic component. The board includes a first surface, a hole, and a first electroconductive portion. The first surface faces the electronic component. The hole is on the first surface. The first electroconductive portion is on at least one of the first surface and an inner surface of the hole. The electronic component has a first terminal. The first terminal has an extension portion. The extension portion extends in a second direction intersecting a first direction. The second direction is a thickness direction of the board. The extension portion has at least a part inserted into the hole. The connection portion has electroconductivity. The connection portion is between the first electroconductive portion and the extension portion.

### CROSS-REFERENCE TO RELATED APPLICATION

This application is a continuation of International Application No. PCT/JP2022/005423, filed Feb. 10, 2022, and the entire contents of which are incorporated herein by reference.

### FIELD

Embodiments of the present invention relate to a board unit, a memory system, and an electronic device.

### BACKGROUND ART

A portable semiconductor storage device including a connection connector protruding from a case and a storage element housed in the case, and connected to a host connector of a host device to communicate information between itself and the host device is known.

### BRIEF DESCRIPTION OF THE DRAWINGS

FIG. 1A is a plan view showing an overall configuration of a memory system according to a first embodiment.

FIG. 1B is a cross-sectional view showing an overall configuration of the memory system according to the first embodiment.

FIG. 2A is a plan view showing a board constituting the memory system according to the first embodiment.

FIG. 2B is an enlarged plan view showing a hole and a pad provided in the board shown in FIG. 2A.

FIG. 3 is a perspective view showing an electronic component mounted on the board shown in FIG. 2A.

FIG. 4 is an enlarged cross-sectional view showing a connection structure between the pad provided on the board shown in FIG. 2A and a terminal of the electronic component.

FIG. 5A is a plan view showing a board constituting a memory system according to a second embodiment.

FIG. 5B is an enlarged plan view showing a hole and a pad provided in a board shown in FIG. 5A.

FIG. 6A is an enlarged cross-sectional view showing a connection structure between the pad provided on the board shown in FIG. 5A and a terminal of an electronic component.

FIG. 6B is an enlarged cross-sectional view showing a connection structure between the pad provided on a board according to modified example 1 of the second embodiment and the terminal of the electronic component.

FIG. 6C is an enlarged plan view showing a hole provided in a board according to modified example 2 of the second embodiment.

FIG. 6D is an enlarged plan view showing a hole provided in a board according to modified example 3 of the second embodiment.

FIG. 7 is a cross-sectional view showing an overall configuration of an electronic device according to a third embodiment.

FIG. 8 is an enlarged cross-sectional view showing a connection structure between a pad provided on a board constituting the electronic device shown in FIG. 7 and a terminal of an electronic component.

### DETAILED DESCRIPTION

A board unit of an embodiment includes a board, an electronic component, and a connection portion. The electronic component is on the board. The connection portion connects the board and the electronic component. The board includes a first surface, a hole, and a first electroconductive portion. The first surface faces the electronic component. The hole is on the first surface. The first electroconductive portion is on at least one of the first surface and an inner surface of the hole. The electronic component has a first terminal. The first terminal has an extension portion. The extension portion extends in a second direction intersecting a first direction. The second direction is a thickness direction of the board. The extension portion has at least a part inserted into the hole. The connection portion has electroconductivity. The connection portion is between the first electroconductive portion and the extension portion.

A board unit, a memory system, and an electronic device of embodiments will be described with reference to the drawings.

In the following description, components having the same or similar functions are denoted by the same reference signs. Also, duplicate description of the components may be omitted. The drawings are schematic or conceptual, and a relationship between a thickness and a width of each portion, a size ratio between portions, and the like are not necessarily the same as actual ones.

In the present application, the term “parallel” may include cases of “substantially parallel”. In the present application, the term “orthogonal” may include cases of “substantially orthogonal”. In the present application, the term “substantially rectangular shape” may include cases of a “rectangular shape” with a chamfered corner portion. In the present application, the term “the same” may include cases of “substantially the same”. In the present application, the term “connection” may include an electrical connection. That is, in the present application, the term “connection” is not limited to cases in which two members are adjacent to each other with nothing interposed therebetween, and may include cases in which another member is interposed between the two members. The term “memory” is not limited to one including a memory element that stores data according to an accumulation state of charges, and may also include one including a memory element that stores data according to a magnetic state, a resistance state, or the like. Also, the term “storage device” may be a storage device that does not use a semiconductor memory.

First, an X direction, a Y direction, and a Z direction will be defined.

The X direction and the Y direction are directions along a surface of a memory system to be described later. The X direction is a short direction of the memory system. The Y direction is a longitudinal direction of the memory system. That is, the Z direction is a direction that intersects (for example, is orthogonal to) the X direction and the Y direction. In other words, the Z direction is a thickness direction of the memory system (board unit, board). The Z direction is a direction perpendicular to the memory system. In the Z direction, a view in a direction from a first surface to a second surface of the board, which will be described later, may be referred to as a plan view.

A first direction corresponds to the Z direction.

A second direction is a direction intersecting the first direction and corresponds to the Y direction.

A third direction is a direction intersecting the first direction and the second direction and corresponds to the X direction.

### First Embodiment

### <Overall Configuration of Memory System>

An overall configuration of a memory system 1 according to a first embodiment will be described.

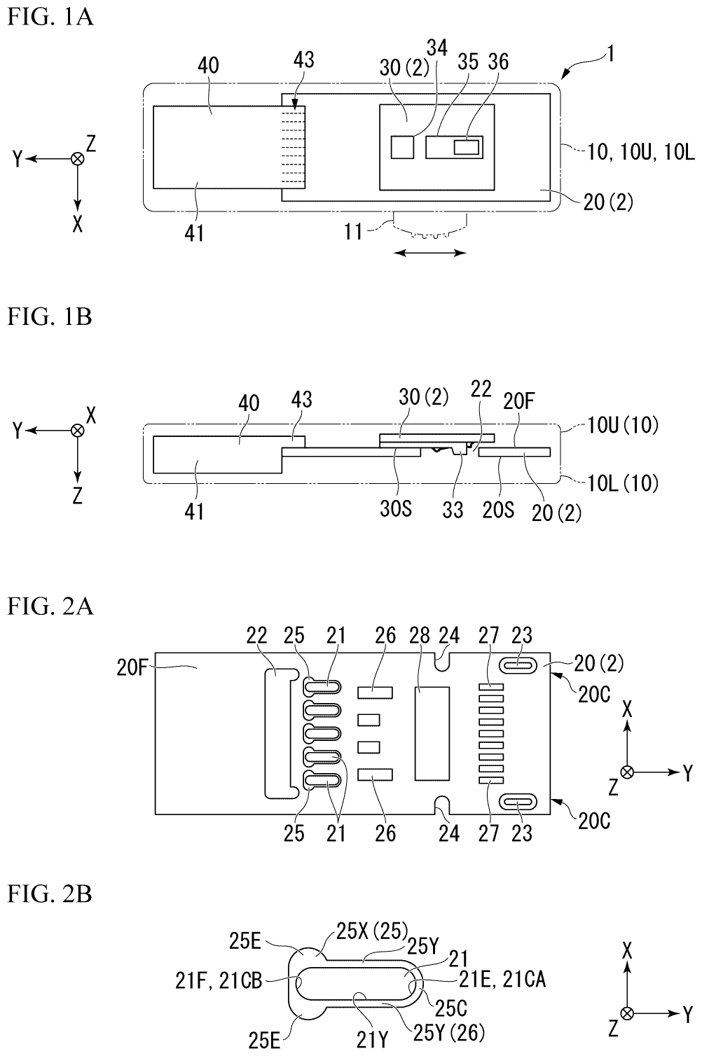

FIG. 1A is a plan view exemplarily showing an overall configuration of the memory system 1. FIG. 1B is a cross-sectional view exemplarily showing the overall configuration of the memory system 1. In FIGS. 1A and 1B, a case to be described later is indicated by a double-dotted-dashed line. FIGS. 1A and 1B mainly show an internal structure of the memory system 1. In other words, FIG. 1A is a perspective plan view with the case transparent, and FIG. 1B is a perspective side view with the case transparent.

The memory system 1 is a device electrically connected to an external device such as a host device. The memory system 1 is one of semiconductor storage devices. The memory system 1 may also be referred to as, for example, a universal serial bus (USB) memory, a USB flash drive (UFD), an electronic device, a semiconductor device, a USB device, a storage device, an auxiliary storage device, or a removable medium.

The memory system 1 according to the first embodiment includes a board unit 2, a case 10, and a connection connector 40. The memory system 1 has a structure including the connection connector 40 and the board unit 2. In the memory system 1, the connection connector 40 and the board unit 2 are movable in the Y direction with respect to the case 10.

### <Case>

The case 10 has a flat shape that is hollow and elongated in the Y direction. The case 10 houses the board unit 2. The case 10 is constituted by, for example, the two of an upper case 10U and a lower case 10L stacked in the Z direction. The case 10 has a moving member 11 movable in the Y direction. The moving member 11 is connected to a board 20 to be described later. The upper case 10U, the lower case 10L, and the moving member 11 are formed of, for example, a hard resin. Types of a resin material are not limited, and a known resin material can be used.

The moving member 11 is movable in the Y direction relative to the case 10. A user of the memory system 1 can cause the connection connector 40 connected to the board 20 to protrude to the outside of the case 10 or store the connection connector 40 inside the case 10 by operating the moving member 11. That is, the case 10 has a storage structure that stores the connection connector 40.

Further, a structure of the case 10 is not limited to the storage structure described above. A structure in which the connection connector 40 is exposed to the outside of the case 10 may also be employed.

### <Connection Connector>

The connection connector 40 is a connector for external connection attached to the board 20.

The connection connector 40 is a portion inserted into, for example, a USB connector (female connector, socket) on a host device side. The connection connector 40 has, for example, a flat rectangular cross-sectional shape. Such a connection connector 40 may also be referred to as, for example, a plug, an insertion portion, or a connecting portion.

The connection connector 40 is a male connector (plug) compliant with, for example, the USB Type-A standard. Furthermore, the standard of the connection connector 40 is not limited to the USB Type-A standard. For example, it may be a male connector (plug) compliant with the USB Type-C standard. The USB Type-C standard includes, for example, the USB 2.0 Type-C standard, the USB 3.1 Gen 1 Type-C standard, and the USB 3.1 Gen 2 Type-C standard.

The connection connector 40 includes an insertion portion 41 and a plurality of connection terminals 43. The insertion portion 41 has a flat rectangular cylindrical shape made of a metal. The number of the plurality of connection terminals 43 is nine in the first embodiment. The connection terminal 43 is an example of a terminal.

### <Board Unit>

FIG. 2A shows the board 20 constituting a part of the board unit 2.

FIG. 2B shows a first hole 21 and a first pad 25 provided on the board 20.

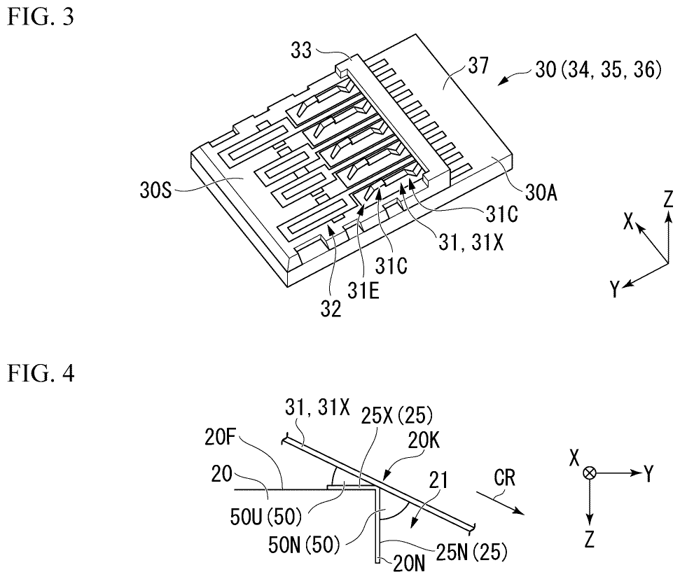

FIG. 3 shows an overall structure of an electronic component 30 mounted on the board 20.

FIG. 4 is an enlarged cross-sectional view showing a connection structure between a first pad 25 and a terminal of the electronic component 30. FIG. 4 partially shows the terminal of the electronic component 30.

The board unit 2 includes the board 20, the electronic component 30, and a connection portion 50. The connection portion 50 connects the board 20 and the electronic component 30.

### <Board>

The board 20 is, for example, substantially a rectangular printed circuit board (PCB).

The board 20 has a first surface 20F and a second surface 20S on a side opposite to the first surface 20F (see FIG. 1B). A plurality of holes are provided on the first surface 20F. These holes are each provided to penetrate the board 20 in the Z direction from the first surface 20F to the second surface 20S. The first surface 20F faces the electronic component 30.

A plurality of pads connected to the electronic component 30 and the plurality of connection terminals 43 of the connection connector 40 are provided on the first surface 20F. The plurality of pads face the electronic component 30.

An electric circuit 28 is provided on the first surface 20F. The electric circuit 28 electrically connects the plurality of connection terminals 43 and the electronic component 30. The electric circuit 28 has, for example, a plurality of signal lines.

### <First Hole, Second Hole, and Third Hole>

Next, the plurality of holes provided in the board 20 will be described.

The board 20 has a plurality of first holes 21, a second hole 22, and two third holes 23. The plurality of first holes 21 are aligned in the X direction. The second hole 22 extends in the X direction. The two third holes 23 are positioned near corner portions 20C of the board 20. Furthermore, the board 20 has two notches 24 provided on both sides in the X direction.

The plurality of first holes 21 are provided in one-to-one correspondence with a plurality of first terminals 31 of the electronic component 30 to be described later. Specifically, the arrangement pitch of the plurality of first holes 21 in the X direction is the same as the arrangement pitch of the plurality of first terminals 31 in the X direction.

In the first embodiment, the number of the plurality of first holes 21 is the same as the number of the plurality of first terminals 31, and is five. As long as the number of the plurality of first holes 21 is the same as the number of the plurality of first terminals 31, the number of the plurality of first holes 21 is not limited to five, and may be four or less or six or more.

The plurality of first holes 21 each have a long hole shape. Specifically, the first holes 21 each have an extending hole portion 21Y, a first curved portion 21CA, and a second curved portion 21CB. The extending hole portion 21Y extends in the Y direction. Each of the first curved portion 21CA and the second curved portion 21CB is positioned at an edge portion of the extending hole portion 21Y in the Y direction. Specifically, the first curved portion 21CA is positioned at one edge portion 21E (first edge portion) of the first hole 21. The second curved portion 21CB is positioned on a side opposite to the first curved portion 21CA, that is, positioned at the other edge portion 21F (second edge portion) of the first hole 21.

The second hole 22 is a portion into which a protruding portion 33 of the electronic component 30 is inserted when the electronic component 30 is mounted on the board 20. In the second hole 22, a width in the X direction is larger than a width in the Y direction. A shape of the second hole 22 is not particularly limited as long as it is possible to avoid interference of the protrusion of the electronic component 30 with the board 20 when the electronic component 30 is mounted on the board 20.

The two notches 24 are portions that engage with protrusion-shaped members provided on inner surfaces of one of the upper case 10U and the lower case 10L. In other words, the two third holes 23 and the two notches 24 are portions used for positioning the board 20 and the case 10 inside the case 10.

### <Pad>

Next, the plurality of pads provided on the board 20 will be described.

The board 20 includes a plurality of first pads 25, a plurality of second pads 26, and a plurality of third pads 27. These plurality of pads 25, 26, and 27 are, for example, copper pads provided on the first surface 20F of the board 20 using a known plating method.

Further, in the first embodiment, a pad is also provided on an inner wall of the board 20 positioned inside the first hole 21 as will be described later.

### <First Pad>

The plurality of first pads 25 are provided in one-to-one correspondence with the plurality of first holes 21. For each of the plurality of first pads 25, one first pad 25 is provided to surround a circumference of one first hole 21. In other words, the first pad 25 can also be referred to as being integrated with the first hole 21. The first pad 25 is an example of a first electroconductive portion.

Specifically, focusing on one first pad 25, the first pad 25 has a Y pad portion 25Y, a pad end portion 25C, an X pad portion 25X, and an inner wall pad portion 25N.

The Y pad portion 25Y, the pad end portion 25C, and the X pad portion 25X are each a pad provided on the first surface 20F, and are each an example of an electroconductive portion.

The Y pad portion 25Y extends parallel to a direction in which the extending hole portion 21Y extends. The pad end portion 25C has a shape following the first curved portion 21CA.

The X pad portion 25X has a shape following the second curved portion 21CB. Furthermore, the X pad portion 25X has a shape different from the pad end portion 25C. The X pad portion 25X extends in the X direction. Therefore, the X pad portion 25X has pad regions 25E positioned on both sides of the first hole 21 on the first surface 20F.

As shown in FIG. 4, the inner wall pad portion 25N is provided on an inner wall 20N of the board 20 positioned inside the first hole 21. A substantially L-shaped three-dimensional pad shape is obtained by the inner wall pad portion 25N and the X pad portion 25X.

Specifically, an edge portion 20K is provided at a boundary between the first hole 21 and the first surface 20F. The X pad portion 25X is provided in a region on the first surface 20F parallel to the Y direction. The region on the first surface 20F includes the edge portion 20K. On the other hand, the inner wall pad portion 25N is provided in a region on the inner wall 20N parallel to the Z direction. The region on the inner wall 20N includes the edge portion 20K. The inner wall 20N is an example of an inner surface of the hole.

### <Second Pad>

The plurality of second pads 26 are provided apart from the plurality of first pads 25 in the Y direction. The second pad 26 is an example of a second electroconductive portion.

The plurality of second pads 26 are provided in one-to-one correspondence with a plurality of second terminals 32 of the electronic component 30 to be described later.

Specifically, the arrangement pitch of the plurality of second pads 26 in the X direction is the same as the arrangement pitch of the plurality of second terminals 32 in the X direction. In the first embodiment, the number of the plurality of second pads 26 is the same as the number of the plurality of second terminals 32, and is four. As long as the number of the plurality of second pads 26 is the same as the number of the plurality of second terminals 32, the number of the plurality of second pads 26 is not limited to four, and may be three or less or five or more.

### <Third Pad>

The plurality of third pads 27 are provided in one-to-one correspondence with the plurality of connection terminals 43 of the connection connector 40 described above. That is, the connection connector 40 is electrically connected to the board unit 2.

The third pad 27 is an example of a third electroconductive portion.

The third pad 27 is disposed apart from the first pad 25 and the second pad 26. In other words, the second pad 26 is disposed between the first pad 25 and the third pad 27 in the Y direction.

In the first embodiment, the number of the plurality of third pads 27 is the same as the number of the plurality of connection terminals 43, and is nine. As long as the number of the plurality of third pads 27 is the same as the number of the plurality of connection terminals 43, the number of the plurality of third pads 27 is not limited to nine, and may be eight or less or ten or more.

### <Electronic Component>

The electronic component 30 is, for example, an integrated circuit (IC) chip having a function of a small USB memory.

The electronic component 30 has a plurality of terminals disposed compliant with the USB standard. That is, the electronic component 30 has the plurality of first terminals 31 and the plurality of second terminals 32.

The electronic component 30 includes a memory 34 and a controller 35 that controls the memory 34. The controller 35 includes an interface circuit 36. The interface circuit 36 is connected to the electric circuit 28 of the board 20 via the plurality of first terminals 31 and the plurality of second terminals 32.

The electronic component 30 includes a seal portion 37 that seals the memory 34 and the controller 35, and a terminal unit 30A that includes the plurality of first terminals 31 and the plurality of second terminals 32. In other words, the terminal unit 30A has a terminal forming surface 30S that overlaps the board 20 in the Z direction, and the protruding portion 33 that protrudes in the Z direction compared to the terminal forming surface 30S.

The terminal forming surface 30S is an example of a first portion. The protruding portion 33 is an example of a second portion.

The plurality of first terminals 31 each include an extension portion 31X extending in the Y direction and having at least a part inserted into the hole. The first terminal 31 is a terminal connected to the first pad 25. A configuration of the extension portion 31X will be described later.

The plurality of second terminals 32 are disposed in one-to-one correspondence with the plurality of second pads 26 in the Z direction. The second terminal 32 is a terminal connected to the second pad 26.

The plurality of first terminals 31 are terminals protruding in the Y direction from the protruding portion 33.

Specifically, focusing on one first terminal 31, as shown in FIG. 3, the first terminal 31 extends in the Y direction from the protruding portion 33 toward a distal end part 31E of the first terminal 31. The first terminal 31 has a bent portion 31C positioned midway between the protruding portion 33 and the distal end part 31E.

In the bent portion 31C, a direction in which the extension portion 31X of the first terminal 31 extends is changed to be directed in an oblique direction (a direction CR to be described later) intersecting the Z direction. That is, the first terminal 31 is a three-dimensional terminal that not only simply extends linearly only in the Y direction but also has a portion that is bent in an oblique direction.

The number of the plurality of first terminals 31 is five as described above. Each of the plurality of first terminals 31 is, for example, a USB 3.0 terminal. The plurality of second terminals 32 are provided on the terminal forming surface 30S. Each of the plurality of second terminals 32 is, for example, a USB 2.0 terminal.

### <Connection Portion>

The connection portion 50 (first connection portion) is a member formed of a material having electroconductivity such as, for example, solder or an electroconductive paste. In the first embodiment, pads provided on the board 20 and terminals of the electronic component 30 are electrically connected using the connection portion 50. Such a connection structure is obtained by a known reflow process.

### <Connection Structure Between Board and Electronic Component>

### <Connection Structure Between First Terminal and First Pad>

As shown in FIG. 1B, the protruding portion 33 of the electronic component 30 is disposed inside the second hole 22 of the board 20. In this state, the plurality of first terminals 31 are disposed one on one inside the plurality of first holes 21.

In the connection structure between the first terminal 31 and the first pad 25 shown in FIG. 4, the extension portion 31X of the first terminal 31 extends in the direction CR intersecting the Z direction. The extension portion 31X is inserted into the first hole 21. The extension portion 31X is electrically connected to the first pad 25 via the connection portion 50. In other words, the connection portion 50 is provided between the first pad 25 and the extension portion 31X.

Specifically, the connection portion 50 has an internal connection portion 50N and an upper surface connection portion 50U. The internal connection portion 50N connects the inner wall pad portion 25N and the extension portion 31X. The upper surface connection portion 50U connects the X pad portion 25X and the extension portion 31X.

In other words, the connection portion 50 is provided between the extension portion 31X and the first surface 20F, and between the extension portion 31X and the inner wall 20N.

Further, the upper surface connection portion 50U is provided on the first pad 25 on the first surface 20F to extend to the pad region 25E of the X pad portion 25X shown in FIG. 2B. Therefore, a contact area of the upper surface connection portion 50U with the first pad 25 increases, and reliability of the electrical connection structure between the first pad 25 and the first terminal 31 increases.

With such a structure, the plurality of first terminals 31 and the plurality of first pads 25 are electrically connected one on one.

Further, as long as the electrical connection structure between the extension portion 31X and the first pad 25 due to the connection portion 50 is obtained, the first pad 25 and the extension portion 31X may or may not be in contact with each other at the edge portion 20K.

### <Connection Structure Between Second Terminal and Second Pad>

As shown in FIG. 1B, the terminal forming surface 30S of the electronic component 30 is in contact with the first surface 20F of the board 20. In this state, the plurality of second terminals 32 provided on the terminal forming surface 30S are connected to the plurality of second pads 26 one on one via a connection member (second connection portion) such as solder or an electroconductive paste.

According to the memory system 1 according to the first embodiment having such a structure, the first terminal 31 and the first pad 25 can be electrically connected with the protruding portion 33 of the electronic component 30 disposed in the second hole 22 of the board 20. Therefore, a thickness of the board unit 2 in the Z direction can be reduced in the memory system 1.

The case 10 constituting the memory system 1 can be made thinner by reducing the thickness of the board unit 2. That is, a thickness of the memory system 1 can be made small.

Further, in the first embodiment, a structure in which the first pad 25 is provided on the first surface 20F, and the inner wall pad portion 25N is provided on the inner wall 20N has been described. A structure in which the first pad 25 is not provided on the first surface 20F, that is, a structure in which the inner wall pad portion 25N and the extension portion 31X are connected only by the internal connection portion 50N may be employed.

Further, a structure in which the inner wall pad portion 25N is not provided on the inner wall 20N, that is, a structure in which the first pad 25 and the extension portion 31X are connected only by the upper surface connection portion 50U may be employed.

### Second Embodiment

A memory system according to a second embodiment will be described.

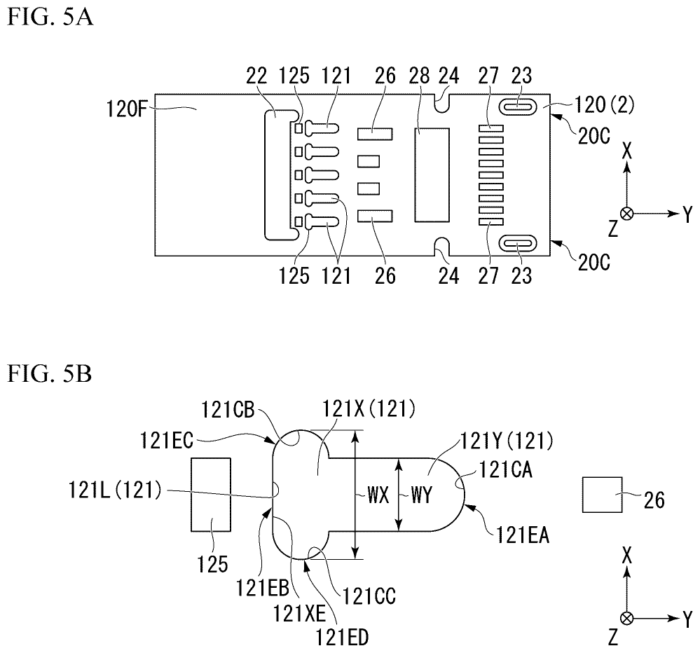

FIG. 5A shows a board 120 constituting a part of a board unit 2.

FIG. 5B shows a first hole 121, a first pad 125, and a second pad 26 provided in the board 120.

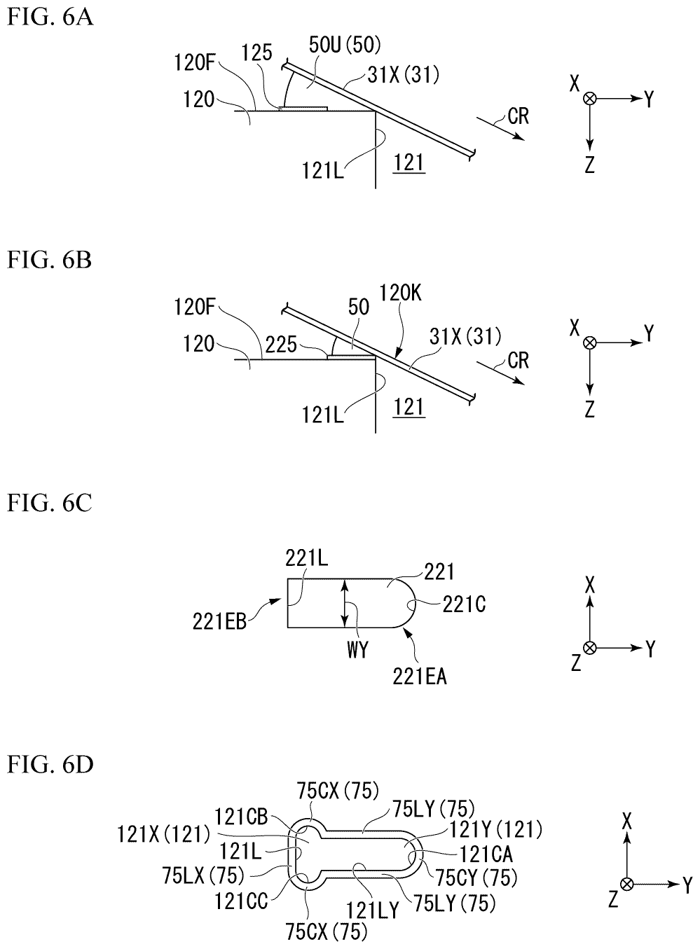

FIG. 6A is an enlarged cross-sectional view showing a connection structure between the first pad 125 and a terminal of an electronic component 30.

In the second embodiment, members the same as those in the first embodiment will be denoted by the same reference signs, and description thereof will be omitted or simplified. The second embodiment is different from the first embodiment in structures of the first hole and the first pad.

### <Board>

The board 120 has a plurality of first holes 121 and a plurality of first pads 125.

The plurality of first holes 121 and the plurality of first pads 125 are provided on a first surface 120F of the board 120.

Configurations of the board 120 other than the first hole 121 and the first pad 125 are the same as those of the board 20 in the first embodiment described above.

### <First Hole>

The plurality of first holes 121 are aligned in the X direction. The plurality of first holes 121 are provided in one-to-one correspondence with a plurality of first terminals 31 of the electronic component 30. The number of the plurality of first holes 121 is the same as the number of the first holes 21 of the first embodiment described above.

The plurality of first holes 121 each have a shape in which two long holes are combined. Specifically, each of the plurality of first holes 121 has a first extending hole portion 121Y extending in the Y direction and a second extending hole portion 121X extending in the X direction. Due to the combination of the first extending hole portion 121Y and the second extending hole portion 121X, the first hole 121 has a substantially T-shaped shape in a plan view.

The first extending hole portion 121Y is an example of a first elongated hole portion. In a plan view, the first extending hole portion 121Y is long in the Y direction.

The second extending hole portion 121X is an example of a second elongated hole portion. In a plan view, the second extending hole portion 121X is long in the X direction.

The first extending hole portion 121Y has two edge portions 121EA and 121EB. A curved portion 121CA is provided on the edge portion 121EA (first edge portion in the Y direction). A linear portion 121L is provided on the edge portion 121EB (second edge portion in the Y direction). The edge portion is an example of a hole edge exposed at the hole. The board 120 has the hole edge. In other words, the hole edge is part of the board 120.

The second extending hole portion 121X is provided at the second edge portion in the Y direction of the first extending hole portion 121Y, that is, at the edge portion 121EB. The second pad 26 is positioned closer to the edge portion 121EA than to the edge portion 121EB. In other words, in the Y direction, a distance between the second pad 26 and the edge portion 121EA is smaller than a distance between the second pad 26 and the edge portion 121EB.

The second extending hole portion 121X is provided in the edge portion 121EB. The second extending hole portion 121X has two edge portions 121EC and 121ED. A curved portion 121CB is provided on the edge portion 121EC (first edge portion in the X direction). A curved portion 121CC is provided on the edge portion 121ED (second edge portion in the X direction).

In the Y direction, the second extending hole portion 121X has an edge portion 121XE. A position of the edge portion 121XE is the same as a position of the linear portion 121L. In the following description, the linear portion 121L and the edge portion 121XE may be simply referred to as the linear portion 121L. As will be described later, the linear portion 121L is a portion adjacent to or in contact with an extension portion 31X of the first terminal 31.

A distance WX between the curved portion 121CB and the curved portion 121CC of the second extending hole portion 121X is larger than a width WY of the first extending hole portion 121Y in the X direction.

In other words, the length of the second extending hole portion 121X in the X direction is larger than the length of the first extending hole portion 121Y in the X direction.

### <First Pad>

The plurality of first pads 125 are provided in one-to-one correspondence with the plurality of first holes 121. The first pad 125 is provided at a position spaced apart from the first hole 121 in the Y direction. In other words, unlike the first embodiment, the first pad 125 is not provided to surround a circumference of the first hole 121.

In the example shown in FIG. 5B, a shape of the first pad 125 is rectangular, but a shape of the first pad 125 is not limited. For example, a shape of the first pad 125 may be oval or circular.

### <Connection Structure Between First Terminal and First Pad>

In a connection structure between the first terminal 31 and the first pad 125 shown in FIG. 6A, the extension portion 31X of the first terminal 31 extends in a direction CR intersecting the Z direction. The extension portion 31X is inserted into the first hole 121. The extension portion 31X is electrically connected to the first pad 125 via a connection portion 50.

Specifically, the connection portion 50 is an upper surface connection portion 50U provided on the first surface 120F of the board 120. The upper surface connection portion 50U connects the first pad 125 and the extension portion 31X. The connection portion 50 is provided at least at a position adjacent to the linear portion 121L.

In other words, the connection portion 50 is provided at least at a position adjacent to the second extending hole portion 121X.

Further, since the first hole 121 has the linear portion 121L, when the extension portion 31X is in contact with the linear portion 121L, a position of the extension portion 31X is stabilized, and the extension portion 31X being deviated in the X direction is suppressed.

With such a structure, the plurality of first terminals 31 and the plurality of first pads 125 are electrically connected one on one.

Further, in the second embodiment, the first pad 125 is positioned to be separated from the first hole 121. A shape and size of the first pad 125 can be changed as appropriate according to a design. When an area of the first pad 125 is increased, a contact area of the upper surface connection portion 50U with the first pad 125 increases, and reliability of the electrical connection structure between the first pad 125 and the first terminal 31 increases.

According to the memory system according to the second embodiment having such a structure, the same or similar effects as those of the first embodiment described above can be obtained. Therefore, a case 10 constituting the memory system 1 can be made thinner by reducing a thickness of the board unit 2. That is, a thickness of the memory system 1 can be made small. Furthermore, according to the second embodiment, since the first hole 121 has the linear portion 121L, an alignment accuracy of the extension portion 31X in the first hole 121 can be improved.

The distance WX of the second extending hole portion 121X is larger than the width WY of the first extending hole portion 121Y. Therefore, an effect that the extension portion 31X of the first terminal 31 is easily inserted into the first hole 121 can also be obtained.

Further, the inner wall pad portion 25N (see FIG. 4) is not provided in the example shown in FIG. 6A, but the second embodiment is not limited to the structure shown in FIG. 6A. Similarly to the first embodiment, an inner wall pad portion 25N may be provided on an inner wall surface inside the first hole 121 of the board 120. In this case, the extension portion 31X is connected to the inner wall pad portion 25N via an internal connection portion 50N.

### Modified Example 1 of Second Embodiment

Modified example 1 of the second embodiment will be described.

FIG. 6B is an enlarged cross-sectional view showing a connection structure between a first pad 225 and a terminal of the electronic component 30.

In modified example 1, members the same as those in the second embodiment will be denoted by the same reference signs, and description thereof will be omitted or simplified. Modified example 1 is different from the second embodiment described above in a disposition of the first pads.

### <First Pad>

The first pad 225 is not separated from the first hole 121 in the Y direction.

Specifically, an edge portion 120K is provided at a boundary between the first hole 121 and the first surface 120F. The first pad 225 is provided in a region on the first surface 120F parallel to the Y direction. The region on the first surface 120F includes the edge portion 120K.

Even in such modified example 1, the same or similar effects as those of the second embodiment described above can be obtained.

### Modified Example 2 of Second Embodiment

Modified example 2 of the second embodiment will be described.

FIG. 6C shows a first hole 221 provided in the board 120.

In modified example 2, members the same as those in the second embodiment will be denoted by the same reference signs, and description thereof will be omitted or simplified. Modified example 2 is different from the second embodiment described above in a shape of the first hole.

### <First Hole>

The first hole 221 extends in the Y direction. The first hole 221 has two edge portions 221EA and 221EB. A curved portion 221C is provided on the edge portion 221EA (first edge portion in the Y direction). A linear portion 221L is provided on the edge portion 221EB (second edge portion in the Y direction). The first hole 221 has a width WY in the X direction. That is, a length of the linear portion 221L is the width WY.

Even in such modified example 2, the same or similar effects as those of the second embodiment described above can be obtained.

Since the linear portion 221L is provided in the first hole 221, when the extension portion 31X is in contact with the linear portion 221L, a position of the extension portion 31X is stabilized, and the extension portion 31X being deviated in the X direction is suppressed.

Further, unlike the second embodiment described above, the second extending hole portion 121X described above is not provided in the first hole 221 according to the present modified example 2. Therefore, a length of the linear portion 221L of the present modified example 2 is reduced compared to that of the linear portion 121L of the second embodiment. Therefore, when the extension portion 31X is inserted into the first hole 221, an amount of deviation of the extension portion 31X in the X direction is limited. Therefore, a positional accuracy of the extension portion 31X in the first hole 221 can be improved.

Further, the first hole 221 shown in modified example 2 may be applied to the board 20 described in the first embodiment.

### Modified Example 3 of Second Embodiment

Modified example 3 of the second embodiment will be described.

FIG. 6D shows the first hole 121 provided in the board 120 and a first pad 75 provided around the first hole 121.

In modified example 3, members the same as those in the second embodiment will be denoted by the same reference signs, and description thereof will be omitted or simplified. Modified example 3 is different from the second embodiment described above in that the first pad is provided around the first hole.

The first pad 75 provided around the first hole 121 is not separated from the first hole 121 in the X direction and the Y direction.

The first pad 75 has a Y pad linear portion 75LY, a Y pad curved end portion 75CY, an X pad linear portion 75LX, and two X pad curved end portions 75CX.

Each of the Y pad linear portion 75LY, the Y pad curved end portion 75CY, the X pad linear portion 75LX, and the two X pad curved end portions 75CX is a pad provided on the first surface 120F, and is an example of an electroconductive portion.

The Y pad linear portion 75LY extends parallel to a direction in which the linear portion 121LY of the first extending hole portion 121Y extends. The Y pad curved end portion 75CY has a shape following the curved portion 121CA.

The X pad linear portion 75LX has a shape following the linear portion 121L. The X pad linear portion 75LX has a shape different from the Y pad curved end portion 75CY. The X pad linear portion 75LX extends in the X direction.

One of the two X pad curved end portions 75CX has a shape following the curved portion 121CB, and the other of the two X pad curved end portions 75CX has a shape following the curved portion 121CC.

In such modified example 3, the Y pad linear portion 75LY, the Y pad curved end portion 75CY, the X pad linear portion 75LX, and the two X pad curved end portions 75CX are provided around the first hole 121. Therefore, the extension portion 31X and the first pad 75 can be electrically connected via the connection portion 50.

Particularly, in modified example 3, the X pad linear portion 75LX is provided to follow the linear portion 121L. When the extension portion 31X is in contact with the linear portion 121L, a position of the extension portion 31X is stabilized, and in this state, the X pad linear portion 75LX and the extension portion 31X can be electrically connected.

Further, the structure of the first hole 121 and the first pad 75 shown in modified example 3 may be applied to the board 20 described in the first embodiment.

### Third Embodiment

An electronic device according to a third embodiment will be described.

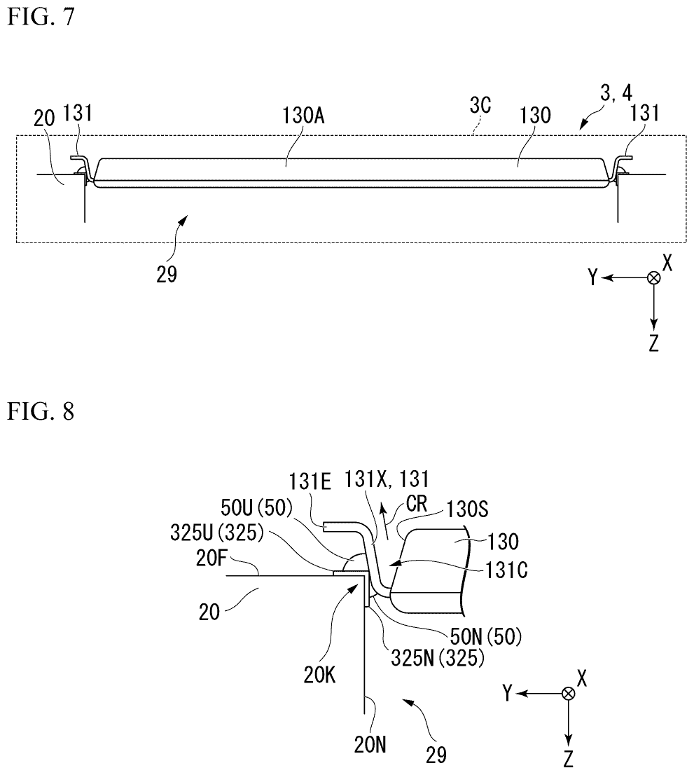

FIG. 7 shows an overall configuration of an electronic device 3. Furthermore, in FIG. 7, a part of a board unit 4 is shown. In FIG. 7, an outer shape of a case 3C that houses the board unit 4 is indicated by a dotted line.

FIG. 8 shows a connection structure between a pad 325 provided on a board 20 of the board unit 4 and a terminal 131 of an electronic component 130.

In the third embodiment, members the same as those in the first embodiment and the second embodiment will be denoted by the same reference signs, and description thereof will be omitted or simplified. The third embodiment is different from the first embodiment and the second embodiment in a structure of the board and the electronic component.

### <Board>

The board 20 has a component disposition hole 29 in which a part of the electronic component 130 is accommodated.

The component disposition hole 29 has a shape corresponding to an outer shape of the electronic component 130.

The board 20 has a plurality of pads 325. The plurality of pads 325 each have an upper surface pad 325U and an inner wall pad portion 325N.

In the example shown in FIGS. 7 and 8, the plurality of pads 325 are aligned in the X direction. Although not shown in FIGS. 7 and 8, the board 20 may include the plurality of pads 325 aligned in the Y direction.

As shown in FIG. 8, the inner wall pad portion 325N is provided on an inner wall 20N of the board 20 positioned inside the component disposition hole 29. A substantially L-shaped three-dimensional pad shape is obtained by the inner wall pad portion 325N and the upper surface pad 325U.

Specifically, an edge portion 20K is provided at a boundary between the component disposition hole 29 and a first surface 20F. The upper surface pad 325U is provided in a region on the first surface 20F parallel to the Y direction. The region on the first surface 20F includes the edge portion 20K. In contrast, the inner wall pad portion 325N is provided in a region on the inner wall 20N parallel to the Z direction. The region on the inner wall 20N includes the edge portion 20K.

### <Electronic Component>

The electronic component 130 shown in FIG. 7 is, for example, a semiconductor package. This semiconductor package may not have a function of a small USB memory.

Examples of such semiconductor packages include IC packages such as a quad flat package (QFP) and a small outline package (SOP).

The electronic component 130 includes a package main body 130A and a plurality of terminals 131 protruding to the outside from a side surface 130S of the package main body 130A.

In the example shown in FIGS. 7 and 8, only the plurality of terminals 131 aligned in the X direction are shown, but the electronic component 130 may include the plurality of terminals 131 aligned in the Y direction.

The terminal 131 extends to be directed toward a distal end part 131E of the terminal 131 from the side surface 130S. The terminal 131 has a bent portion 131C positioned midway between the side surface 130S and the distal end part 131E.

In the bent portion 131C, a direction in which an extension portion 131X of the terminal 131 extends is changed to be directed in an oblique direction (direction CR) intersecting the Z direction. That is, the terminal 131 is a three-dimensional terminal that not only simply extends linearly in the Z direction or the Y direction, but also has a portion that is bent in an oblique direction.

### <Connection Structure Between Terminal and Pad>

As shown in FIG. 8, the package main body 130A of the electronic component 130 is disposed in the component disposition hole 29 of the board 20. In this state, the plurality of terminals 131 are disposed in one-to-one correspondence with the plurality of pads 325.

In the connection structure between the terminal 131 and the pad 325, the extension portion 131X of the terminal 131 extends in the direction CR intersecting the Z direction. The extension portion 131X is inserted into the component disposition hole 29. The extension portion 131X is electrically connected to the pad 325 via a connection portion 50. In other words, the connection portion 50 is provided between the pad 325 and the extension portion 131X.

Specifically, the connection portion 50 includes an internal connection portion 50N and an upper surface connection portion 50U. The internal connection portion 50N connects the inner wall pad portion 325N and the extension portion 131X. The upper surface connection portion 50U connects the upper surface pad 325U and the extension portion 131X.

With such a structure, the plurality of terminals 131 and the plurality of pads 325 are electrically connected one on one.

Further, in the edge portion 20K, as long as the electrical connection structure between the extension portion 131X and the pad 325 due to the connection portion 50 is obtained, the pad 325 and the extension portion 131X may or may not be in contact with each other.

According to the electronic device 3 according to the third embodiment having such a structure, the terminal 131 and the pad 325 can be electrically connected with the package main body 130A of the electronic component 30 disposed in the component disposition hole 29 of the board 20. Therefore, in the electronic device 3, a thickness of the board unit 4 in the Z direction can be made small. A thickness of the electronic device 3 can be made small by reducing the thickness of the board unit 4.

According to at least one embodiment described above, the electronic component has a terminal including an extension portion extending in a direction intersecting a thickness direction of the board to be inserted into the hole, and the connection portion has electroconductivity and is provided between the pad and the extension portion. Therefore, thicknesses of the board unit, the memory system, and the electronic device can be made small.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A board unit comprising:
a board;
an electronic component on the board; and
a connection portion connecting the board and the electronic component, wherein
the board includes:
a first surface facing the electronic component;
a hole on the first surface; and
a first electroconductive portion on at least one of the first surface and an inner surface of the hole,
the electronic component has a first terminal, the first terminal has an extension portion,
the extension portion extends in a second direction intersecting a first direction,
the second direction is a thickness direction of the board,
the extension portion has at least a part inserted into the hole,
the connection portion has electroconductivity, and
the connection portion is between the first electroconductive portion and the extension portion.

2. The board unit according to claim 1, wherein
the first electroconductive portion has an electroconductive portion on the first surface.

3. The board unit according to claim 2, wherein
the electroconductive portion is adjacent to the hole on the first surface.

4. The board unit according to claim 3, wherein
the first electroconductive portion is on the first surface and the inner surface of the hole, and
the connection portion is between the extension portion and the first surface and between the extension portion and the inner surface of the hole.

5. The board unit according to claim 1, wherein
the board has a hole edge exposed at the hole,
the hole edge has a part having a linear portion extending linearly in a third direction intersecting the first direction and the second direction, and
the connection portion is at least at a position adjacent to the linear portion.

6. The board unit according to claim 1, wherein
the hole has:
a first elongated hole portion having a first edge portion and a second edge portion in the second direction, the first elongated hole portion being long in the second direction when viewed from the first direction; and
a second elongated hole portion at the second edge portion of the first elongated hole portion, the second elongated hole portion being long in a third direction intersecting the first direction and the second direction, and wherein
a length of the second elongated hole portion in the third direction is larger than a length of the first elongated hole portion in the third direction, and
the connection portion is at least at a position adjacent to the second elongated hole portion.

7. The board unit according to claim 6, wherein
the first surface of the board includes a second electroconductive portion,
the second electroconductive portion is apart from the first electroconductive portion,
the electronic component has a second terminal corresponding to the second electroconductive portion in the first direction,
the second terminal is connected to the second electroconductive portion, and
the second electroconductive portion is closer to the first edge portion than to the second edge portion.

8. The board unit according to claim 1, wherein
the board has a plurality of holes including the hole,
the plurality of holes are in a third direction intersecting the first direction and the second direction,
the electronic component includes a plurality of first terminals including the first terminal,
the plurality of first terminals are in the third direction in one-to-one correspondence with the plurality of holes, and
each of the plurality of first terminals has the extension portion.

9. The board unit according to claim 1, wherein
the electronic component includes a memory, a controller controlling the memory, and an interface circuit connected to the controller, and
the first terminal is connected to the interface circuit.

10. The board unit according to claim 9, wherein
the electronic component includes a plurality of terminals compliant with the USB standard, and
the first terminal is one terminal included in the plurality of terminals.

11. The board unit according to claim 9, wherein
the electronic component includes a seal portion sealing the memory, the controller, and the interface circuit, and a terminal unit including a plurality of terminals,
the terminal unit includes a first portion and a second portion,
the first portion overlaps the board in the first direction,
the second portion protrudes in the first direction compared to the first portion,
the board has a hole, and
the second portion is inserted into the hole.

12. A memory system comprising:
a board unit according to claim 9;
a case housing the board unit; and
a connector electrically connectable to an external device, wherein
a first surface of the board has a third electroconductive portion,
the third electroconductive portion is apart from the first electroconductive portion, and
the third electroconductive portion is connected to the connector.

13. An electronic device comprising:
a board unit according to claim 9; and
a case housing the board unit.
